(19) United States
(12) Patent Application Publication
(10) Pub. No.: US 2008/0212386 A1
(43) Pub. Date: Sep. 4, 2008

(54) SEMICONDUCTOR MEMORY DEVICE, SEMICONDUCTOR DEVICE, MEMORY SYSTEM AND REFRESH CONTROL METHOD

(75) Inventor: Yoshiro RIHO, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/964,303

(22) Filed: Dec. 26, 2007

(30) Foreign Application Priority Data
Dec. 26, 2006 (JP) 2006-350684

(51) Int. Cl. G11C 7/00; G11C 8/00

(52) U.S. Cl. 365/222; 365/230.03

(57) ABSTRACT

A semiconductor memory device comprises: a memory cell array in which memory cells are divided into banks; cache memories each for storing data of a word line selected by a row address; a setting register for setting a data holding capacity so that a holding area where data is held during a self refresh period and a non-holding area where data is not held during the self refresh period are commonly included in each bank; a refresh controller for outputting a row address to be refreshed at predetermined intervals during the self refresh period and for performing a refresh operation for a selected word line corresponding to the row address in an activated bank; and a bank controller for activating all banks when the selected word line is included in the holding area and inactivating all banks when the selected word Line is included in the non-holding area.

### BACKGROUND OF THE INVENTION

1. Field of the Invention

The present invention relates to a refresh technique for semiconductor memory devices such as DRAMs (Dynamic Random Access Memories), and particularly relates to a technique of a partial array self refresh method for refreshing partial areas set in a memory cell array to reduce consumption current in a standby mode.

2. Description of the related art

In recent years, a large-capacity DRAM tends to be mounted in a mobile device such as a cellular phone. To achieve lower power consumption when the mobile device is in a standby mode, it is desired to reduce consumption current in a self refresh operation of the DRAM. Therefore, a partial array self-refresh method (hereinafter referred to as “PASR”) is proposed (e.g., see Japanese Patent Application Laid-open No. 2004-118938). According to the PASR, in a memory cell array which generally includes a plurality of banks, a self refresh operation is selectively performed for one or some of the banks. In this case, data required to be held is stored in a certain bank, and the self refresh operation may be performed only for this bank.

FIG. 13 shows a setting example of the above PASR. According to the PASR, for example, a predetermined set command is input, so that setting information of the PASR is written into a part of a setting register (lower three bits shown in FIG. 13). If the DRAM has four banks A, B, C and D in total, the number of banks as refresh targets whose data should be held can be selectively set to one of three settings including “all banks”, “two banks” (banks A/B) and “one bank” ( bank A) based on the setting information. The selection of banks is performed based on a 2-bit bank select address BA0 and BA1 as shown in FIG. 13.

FIG. 14 is a block diagram showing a principal configuration of the DRAM for achieving control of the PASR shown in FIG. 13. In FIG. 14, only a portion of the entire configuration of the DRAM is shown, which includes a self refresh controller 101, a PASR state controller 102, and a bank activation controller 103. A PASR Entry/Exit signal is input to the self refresh controller 101, the PASR state controller 102 and the bank activation controller 103, respectively, at the start/end of the self refresh operation. Further, control signals corresponding to two types of refresh target banks (two banks/one bank) as the setting information of the PASR in FIG. 13 are input to the PASR state controller 102.

When the self refresh operation is started, the refresh counter 101b counts up and outputs a row address sequentially in synchronization with an internal clock generated at predetermined intervals from a self refresh oscillator 101a of the self refresh controller 101. In the PASR state controller 102, a register R10 is set to a high level when two banks are set, and a register R11 is set to a high level when one bank is set, in response to the setting information in FIG. 13. Outputs of two registers R10 and R11 are coupled to one input terminals of two AND gates A10 and A11, while the PASR Entry/Exit signal is coupled to the other input terminals thereof, and the AND gates A10 and A11 output bank stop signals S1 and S2 respectively.

In the bank activation controller 103, one of four decode signals is selectively activated in a normal mode in accordance with the 2-bit bank select address BA0 and BA1 input to the bank selection decoder 104. Meanwhile, all the four decode signals are activated during a self refresh period by the PASR Entry/Exit signal input to the bank selection decoder 104. The four decode signals are respectively input to bank active signal generators 105a, 105b, 105c and 105d of the respective banks A to D. Further, the bank stop signal S1 is input to the bank active signal generators 105c and 105d of the banks C and D, and the bank stop signal S2 is input to the bank active signal generators 105b, 105c and 105d of the banks B, C and D.

Each of bank active signal generators 105a to 105d activates each of the bank active signals Aa, Ab, Ac and Ad output to a corresponding bank when input bank stop signals S1 and/or S2 are in an inactivated state (low level) and an input decode signal is in an activated state (high level). Thereby, when the self refresh operation is performed for one bank, only the bank active signal Aa is activated, while when the self refresh operation is performed for two banks, only two bank active signals Aa and Ab are activated. During the self refresh period, the refresh operation is performed in which only selected word lines in a bank to be refreshed are activated according to a row address output at predetermined intervals from the refresh counter 101b, and the refresh operation for banks which are not refresh targets is suspended.

FIG. 15 is a diagram showing an example of the self refresh operation in which one bank (bank A) is set to be refreshed. During the self refresh period, the internal clock is output at intervals t0 from the self refresh oscillator 101a, and an internal command REF synchronizing therewith is supplied from a command decoder. At this point, the bank A is designated as a refresh target in accordance with the setting information in the setting register, and thereby only the bank active signal Aa is selectively activated in the configuration of FIG. 14. Thus, a refresh operation for a selected word line in the bank A is performed, and refresh operations for other banks B, C and D are not performed. The same operation is repeated at the intervals t0 until the end of the self refresh period. This operation allows the number of banks as refresh targets is reduced during the self refresh period, and thus correspondingly the consumption current of the DRAM in the stand-by mode can be reduced.

Generally, in the memory cell array of DRAM, data of the memory cells on the selected word line is read by a sense amplifier row, and thereafter the sense amplifier row functions as a cache memory. In this case, a cache capacity in a case of activating and accessing one bank is equivalent to one page corresponding to the selected word line. Meanwhile, when all banks are activated and accessed simultaneously, for example, in a DRAM of four bank configuration, the cache capacity corresponding to four pages can be available.

However, if the number of banks to be refreshed is limited in the PASR, the banks to be refreshed are only activated and data is held during the self refresh period of DRAM. Meanwhile, data of banks which are not refresh targets is erased including one page data stored in the cache memory by the self refresh operation. Generally, in a DRAM mounted on a mobile device, the self refresh operation is frequently performed in the standby mode, and thus it is desirable to hold data in the cache memory during the self refresh period. However, the PASR needs to be set so that all banks are refreshed in order to maximize the cache capacity, and thus the consumption current cannot be reduced in the standby mode. In this manner, a problem arises in that it is difficult to achieve both the maximization of the cache capacity of all banks and a reduction in the consumption current in the PASR by the conventional DRAM.

### BRIEF SUMMARY OF THE INVENTION

An object of the present invention is to provide a semiconductor memory device capable of reducing consumption current in a standby mode by limiting areas for holding data in self refresh operation while effectively utilizing cache memories attached to a plurality of banks.

An aspect of the present invention is a semiconductor memory device comprising: a memory cell array in which memory cells arranged at intersections between a plurality of word lines and a plurality of bit lines are divided into a plurality of banks; a plurality of cache memories which is attached to the respective banks and each stores data of a word line selected by a row address; a setting means for setting a data holding capacity of said memory cell array so that a holding area in which data is held during a self refresh period and a non-holding area in which data is not held during the self refresh period are commonly included in each of the plurality of banks; a refresh controller for sequentially outputting a row address to be refreshed at predetermined intervals during the self refresh period and for performing a refresh operation for a selected word line corresponding to the row address to be refreshed in an activated bank; and a bank controller for activating all of the plurality of banks when the selected word line is included in the holding area and inactivating all of the plurality of banks when the selected word line is included in the non-holding area, respectively, based on the row address to be refreshed in a self refresh operation performed at the predetermined intervals.

According to the semiconductor memory device of the present invention, when starting the self refresh period in a state where the cache memories attached to all the banks stores data in a normal operation, a row address to be refreshed which is output at a predetermined interval is checked, and refresh operation for the holding area of each bank is performed while refresh operation for the non-holding area of each bank is not performed. In this case, the number of banks for holding data is not limited, however holding areas commonly included in the banks are limited. Therefore, the cache memories can be utilized within a time period extending over the self refresh period, when data included the holding areas of all banks are stored in the cache memories. Accordingly, a reduction in consumption current in a standby mode in the PASR can be achieved without a reduction in an available cache capacity In the semiconductor memory device of the present invention, each of said cache memories may be a sense amplifier row including a plurality of sense amplifiers for amplifying data of the memory cells on the selected word line in the bank through the plurality of bit lines

In the semiconductor memory device of the present invention, said setting may be capable of selectively setting one of M types of the data holding capacities each having ½^{N} (N is an integer between 1 and M) of a storage capacity of said memory cell array. By this, a desired data holding capacity can be selected with a simple configuration.

In the semiconductor memory device of the present invention, said bank controller may determine the holding area and the non-holding area based on a pattern of K bits included in the row address to be refreshed.

In the semiconductor memory device of the present invention, each of the banks may be divided into a plurality of memory mats each having the same storage capacity, and the holding areas and the non-holding areas may be arranged in the respective memory mats.

In the semiconductor memory device of the present invention, the row address may include first bits for selecting the memory mat and second bits for selecting the word line in each of the memory mats, and said bank controller may determine the holding area and the non-holding area based on a pattern of the second bits.

An aspect of the present invention is a semiconductor device having a memory integrated circuit and a logic integrated circuit respectively configured on a single chip, wherein said memory integrated circuit comprises: a memory cell array in which memory cells arranged at intersections between a plurality of word lines and a plurality of bit lines are divided into a plurality of banks; a plurality of cache memories which is attached to the respective banks and each stores data of a word line selected by a row address; a setting means for setting a data holding capacity of said memory cell array so that a holding area in which data is held during a self refresh period and a non-holding area in which data is not held during the self refresh period are commonly included in each of the plurality of banks; a refresh controller for sequentially outputting a row address to be refreshed at predetermined intervals during the self refresh period and for performing a refresh operation for a selected word line corresponding to the row address to be refreshed in an activated bank; and a bank controller for activating all of the plurality of banks when the selected word line is included in the holding area and inactivating all of the plurality of banks when the selected word line is included in the non-holding area, respectively, based on the row address to be refreshed in a self refresh operation at the predetermined intervals, and said logic integrated circuit comprises: a memory controller for controlling a normal operation of said memory integrate circuit and for controlling start/end of a self refresh operation in said memory cell array; and an operation means for performing an operation to achieve a predetermined function using at least data stored in said cache memories.

In the semiconductor device of the present invention, said memory controller may send a command for setting the data holding capacity for said setting means and a command for indicating the start/end of the self refresh operation, respectively, to said memory integrated circuit.

An aspect of the present invention is a memory system comprising: a main memory divided into a plurality of banks; a plurality of cache memories which is attached to the respective banks and each stores data of an area of each bank selected by an address; a setting means for setting a data holding capacity of said main memory so that a holding area in which data is held during a self refresh period and a non-holding area in which data is not held during the self refresh period are commonly included in each of the plurality of banks; a command decoder for controlling a self refresh operation for said main memory when receiving a self refresh request; a refresh controller for sequentially outputting an address to be refreshed at predetermined intervals during the self refresh period and for performing a refresh operation for a selected area corresponding to the address to be refreshed in an activated bank; and a bank controller for activating all of the plurality of banks when the selected area is included in the holding area and inactivating all of the plurality of banks when the selected area is included in the non-holding area, respectively, based on the address to be refreshed in the self refresh operation.

The memory system of the present invention may further comprise a memory controller for instructing said main memory to operate in a normal operation and for instructing said main memory to start/end the self refresh operation.

An aspect of the present invention is a memory system refresh control method for a memory cell array divided into a plurality of banks to each of which a cache memory attached, the method comprising the steps of; setting a data holding capacity of said memory cell array so that a holding area in which data is held during a self refresh period and a non-holding area in which data is not held during the self refresh period are commonly included in each of the plurality of banks; instructing a start of the self refresh period; outputting a row address to be refreshed sequentially at predetermined intervals during the self refresh period; activating all of the plurality of banks when the selected word line is included in the holding area and inactivating all of the plurality of banks when the selected word line is included in the non-holding area, respectively, based on the row address to be refreshed; performing a refresh operation for the selected word line corresponding to the row address to be refreshed in activated banks; and instructing an end of the self refresh period.

In the refresh control method of the present invention, the plurality of banks may be simultaneously activated and refreshed when selected word lines corresponding to the same row address are included in the holding areas of the plurality of banks.

As described above, according to the present invention, a refresh operation for only holding areas commonly set in the plurality of banks can be performed based on a row address to be refreshed during a self refresh period of a semiconductor memory device. Thus, cache memories can be utilized without restriction by PASR when partial data of holding areas of the banks are respectively stored in the cache memories, and thus the maximization of cache capacity and a reduction in consumption current in the PASR can be both achieved when using the semiconductor memory device having the plurality of banks. Further, configuration and effects of the present invention can be achieved in a semiconductor device having a memory integrated circuit and a logic integrated circuit, a memory system, and a refresh control method, in addition to the semiconductor memory device.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIG. 1 is a block diagram showing a schematic entire configuration of a DRAM of an embodiment;

FIG. 2 is a diagram showing a relation of a the memory cell array having four bank configuration with row and column addresses;

FIG. 3 is a diagram showing an expanded configuration of a unit area UR in each of banks A to D;

FIG. 4 is a diagram showing a configuration example of a sense amplifier row SR as a cache memory;

FIG. 5 is a diagram showing a specific setting example of a setting register;

FIG. 6 is a block diagram showing a principal configuration relating to a self refresh operation of the DRAM of the embodiment;

FIG. 7 is a diagram showing a refresh operation during a self refresh period in a case where a holding area corresponding to a predetermined data holding capacity is set for each bank;

FIG. 8 is a diagram in which self refresh operations of FIG. 7 for different data holding capacities of PASR are compared on a time axis;

FIG. 9 is a diagram in which different data holding capacities of the PASR are compared with attention paid to a configuration of a memory mat M;

FIGS. 10A and 10B are diagrams for describing effects in case of employing the PASR of the embodiment;

FIG. 11 is a diagram for describing a case of applying the concept of the PASR of the present invention to a general memory system;

FIG. 12 is a diagram for describing a case of applying the concept of the PASR of the present invention to a SOC (System on chip) as a semiconductor device;

FIG. 13 is a diagram showing a setting example of conventional PASR;

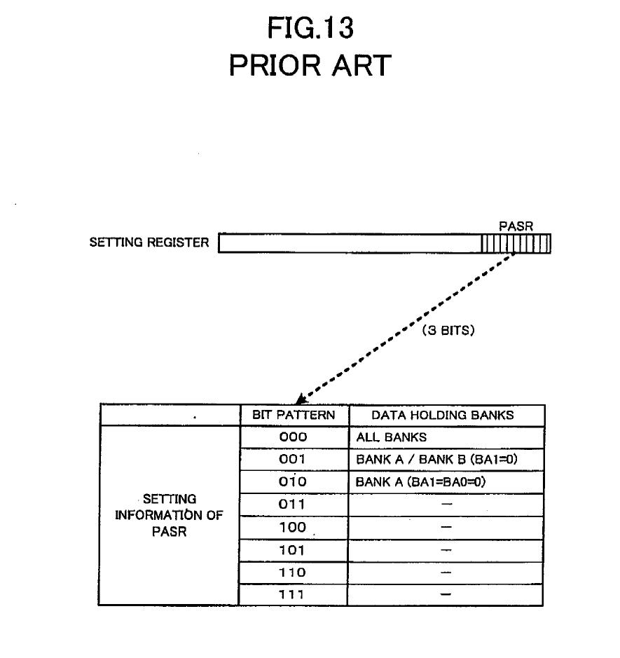

FIG. 14 is a block diagram showing a principal configuration of a DRAM for achieving control of the conventional PASR; and

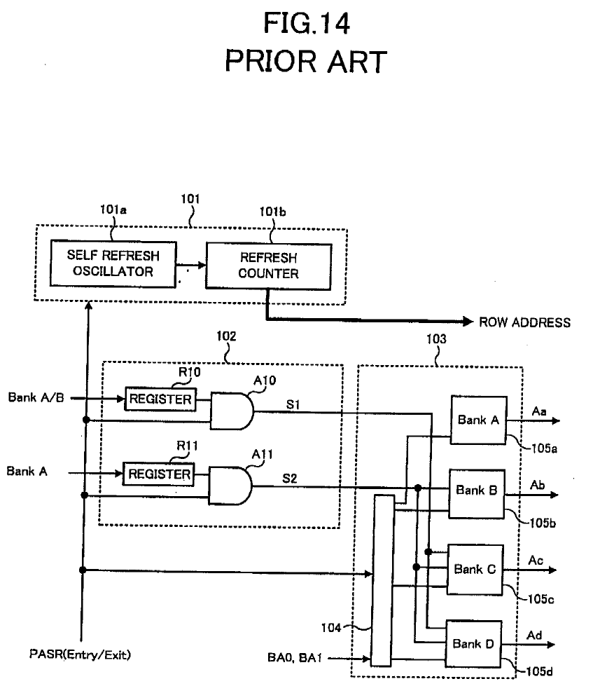

FIG. 15 is a diagram showing an example of a self refresh operation in which one bank (bank A) is set to be refreshed in the conventional PASR.

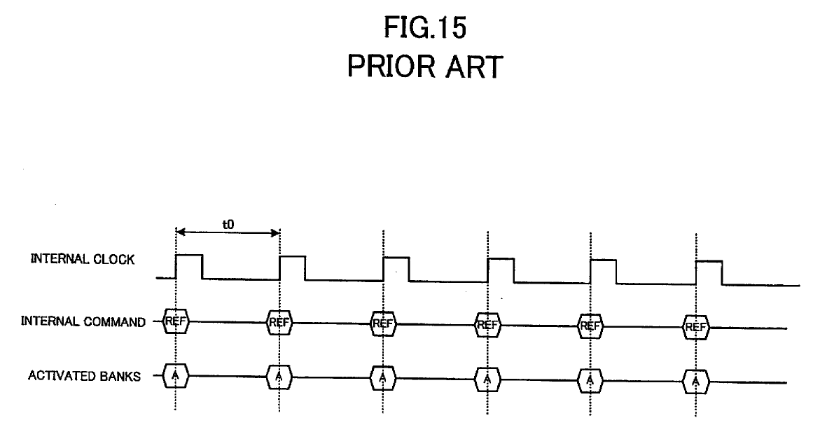

### DETAILED DESCRIPTION OF THE INVENTION

A preferred embodiment of the present invention will be described with reference to the accompanying drawings. In the embodiment, a case of applying the present invention to a DRAM having a configuration for performing a self refresh operation for a memory cell array divined into a plurality of banks will be described.

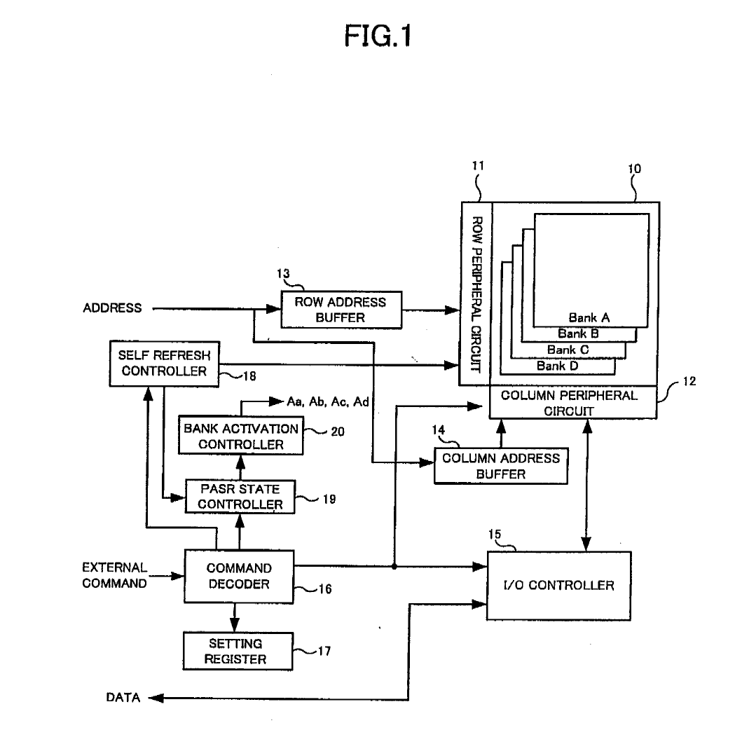

FIG. 1 is a block diagram showing a schematic entire configuration of the DRAM of the embodiment. This embodiment exemplifies a DRAM having an entire storage capacity of 512 Mbits and having a four bank configuration. The DRAM as shown in FIG. 1 includes a memory cell array 10, a row peripheral circuit 11, a column peripheral circuit 12, a row address buffer 13, a column address buffer 14, an I/O controller 15, a command decoder 16, a setting register 17, a self refresh controller 18, a PASR state controller 19, and a bank activation controller 20.

The memory cell array 10 is divided into four banks A, B, C and D, and each bank has the same storage capacity (128 Mbits) and the same configuration. The memory cell array 10 includes many memory cells arranged at intersections between a plurality of word lines and a plurality of bit lines. When accessing the memory cell array 10, a designated bank can be accessed individually. Further, an auto refresh operation in a normal mode and a self refresh operation in a standby mode can be performed for each bank. Regarding the self refresh, it is possible to control a partial refresh for predetermined areas in the four banks A, B, C and D based on the PASR, and specific description thereof will be made later.

The row peripheral circuit 11 is provided attached to the plurality of word lines of the memory cell array 10, and includes row decoders and word drivers. The column peripheral circuit 12 is provided attached to the plurality of bit lines of the memory cell array 10, and includes column decoders and sense amplifier rows. In the row peripheral circuit 11, a word line corresponding to a row address stored in the row address buffer 13 is selected. In the column peripheral circuit 12, a bit line corresponding to a column address stored in the column address buffer 14 is selected. Data of a memory cell corresponding to the selected word line and bit line is input/output from/to outside by the I/O controller 15.

The command decoder 16 decodes an input external command and generates a corresponding internal command or control signal which is sent to each part of the DRAM. Meanwhile, when a predetermined set command is input to the command decoder 16, information required for setting various operation modes of the DRAM is written into the setting register 17. Further, the row address is sent to the row address buffer 13 and the column address is sent to the column address buffer 14, respectively of an address input together with the external command. In the embodiment, a case is described in which a memory cell is selected according to a 14-bit row address and an 8-bit column address, while one of the four banks A, B, C and D is selected according to a 2-bit bank select address.

The self refresh controller 18 controls the self refresh operation in the standby mode of the DRAM, and generates a row address of the word line to be refreshed at predetermined intervals. The PASR state controller 19 holds the setting information of the PASR, and controls to selectively switch whether or not each bank is refreshed based on the row address from the self refresh controller 18. The bank activation controller 20 supplies bank active signals Aa, Ab, Ac and Ad to the banks A, B, C and D respectively in accordance with the switching control of the PASR state controller 19. The PASR state controller 19 and the bank activation controller 20 integrally function as the bank controller of the present invention. Specific configuration and operation of the self refresh controller 18, the PASR state controller 19 and the bank activation controller 20 will be described later.

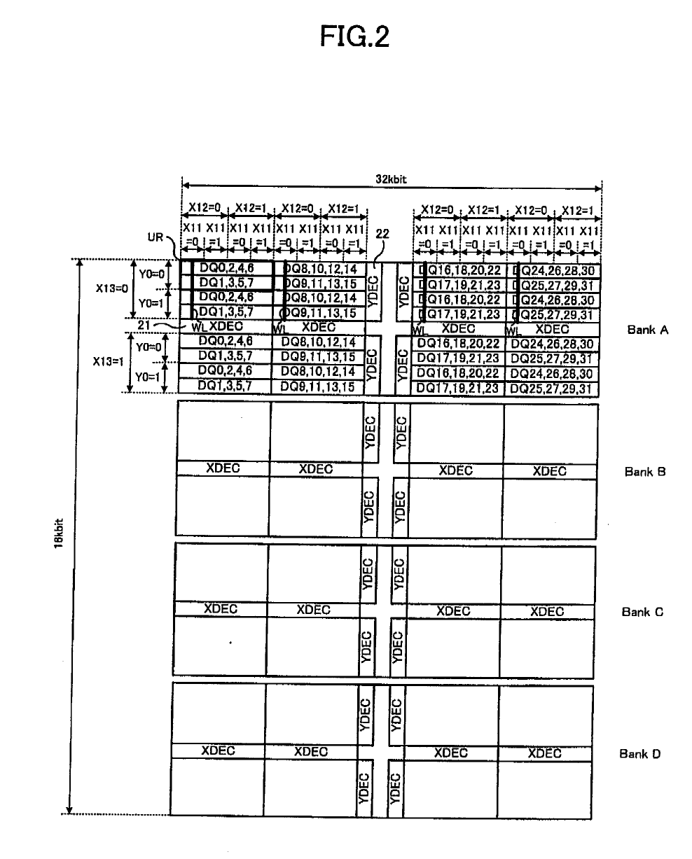

FIG. 2 is a diagram showing a relation of the memory cell array 10 of the four bank configuration with the row and column addresses. The memory cell array 10 is divided into the banks A, B, C and D, each of which is an area including a predetermined number of bit lines. Regarding the bank A located at an upper side of FIG. 2, a relation of upper three bits X11, X12 and X13 of the row address, lower one bit Y0 of the column address, and 32 bits DQ0 to DQ31 is shown. In the following description, the configuration of the bank A is exemplified, but the same configuration is assumed for the other banks B, C and D.

As shown in FIG. 2, the bank A is divided into upper and lower areas sandwiching row decoders (XDEC) 21 aligned along a bit line extending direction, and thereby an upper area corresponding to X13=0 and a lower area corresponding to X13=1 are arranged symmetrically. Further, the bank A is divided into left and right areas sandwiching column decoders (YDEC) 22 aligned along a word line extending direction, and thereby a left area and a right area are arranged symmetrically. Furthermore, each of the upper, lower, left and right areas of the bank A is partitioned into groups each of which corresponds to four bits of DQ (input/output terminal), and unit areas UR are shown, each of which includes two groups each having four bits of DQ. Respective X11, X12, X13 and Y0 are the same in each group in the unit area UR.

For example, a unit area UR having DQ0 to DQ7 is arranged in the upper left area of the bank A, and four unit areas OR corresponding to the same X11, X12, X13 and Y0 are arranged in a bit line extending direction. The four unit areas UR include 32-bit DQ0 to D031. Then, in the entire bank A, 16 unit areas UR in total are arranged, and four sets of the DQ0 to DQ31 (32×4) are included in a word line extending direction. In this manner, the DRAM of the embodiment has a 32-bit input/output configuration, and thus 32-bit data corresponding to a designated address can be simultaneously input/output through the four unit areas UR in the bit line extending direction.

In FIG. 2, a selected word line WL which is activated when a given row address of bank A is designated is indicated with thick lines. The selected word line WL is divided into four lines at either of the upper and lower areas corresponding to X13, and two adjacent unit areas UR determined in response to Y0 are selected so that each memory cell on the selected word line WL can be accessed.

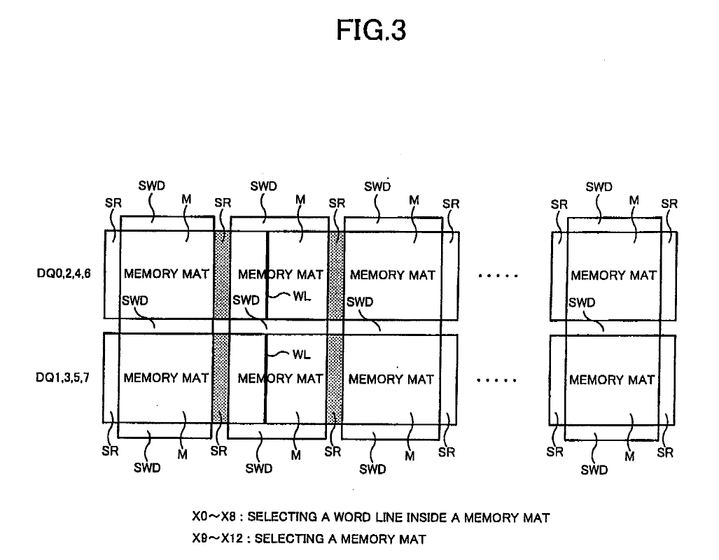

FIG. 3 is a diagram showing an expanded configuration of the unit area UR in each of the banks A to D. As shown in FIG. 3, one unit area UR of FIG. 2 is further divided into 32 memory mats M. 16 memory mats M are aligned in the bit line extending direction, and two memory mats M are aligned in the word line extending direction. Sub-word drivers SWD are arranged at both ends in the word line extending direction of each memory mat M. Further, sense amplifier rows SR are arranged at both ends in the bit line extending direction of each memory mat M. It is possible to access a memory cell being arranged at an intersection of a word line selected by 9 bits X0 to X8 of the row address and a bit line selected by 7 bits Y1 to Y7 of the column address, for each memory mat M as shown in FIG. 3. Further, regarding two memory mats M adjacent in the word line extending direction, DQ0, DQ2, DQ4 and DQ6 are assigned to the upper memory mat M, and DQ1, DQ3, DQS and DQ7 are assigned to the lower memory mat M.

The sub-word driver SWD is a circuit for activating word lines arranged in the upper or lower memory mat M (sub-word lines). FIG. 3 shows a state in which a selected word line WL in two memory mats M adjacent in a longitudinal direction is activated by a corresponding sub-word driver SWD when a given row address is designated. Meanwhile, the sense amplifier row SR includes many sense amplifiers for amplifying data through a plurality of bit lines in the memory mat M, and is shared by two memory mats M on both sides. In the arrangement of FIG. 3, 34 sense amplifier rows SR are included, and four sense amplifier rows SR attached to the two memory mats M including the activated selected word line WL are indicated by hatching.

In the DRAM of the embodiment, the above sense amplifier row SR functions as a cache memory. That is, data read from the memory cells when the selected word line WL in a given bank is activated based on a row address is thereafter held in the sense amplifier row SR. In this state, accessing the DRAM with a designated column address allows data held in the sense amplifier row SR to be output to outside through a certain DQ (column access). For the selected memory mat M, two sense amplifier rows SR on both sides function as the cache memory respectively, and data can be selectively read out in accordance with the column address.

In the entire single bank, since data of the cache memory can be read out through 32-bit DQ based on an 8-bit column address in the column access, data capacity of one page corresponding to the selected word line is equivalent to 8 k bits. Meanwhile, in the DRAM of the embodiment, a case of simultaneously activating the four banks is assumed, in addition to a case of activating the bank selected by the above bank select address BA0 and BA1. In this case, the data capacity of the cache memory of the four banks in the column access is 32 k bits. The relation between the data capacity (cache capacity) of the cache memory and the operation of the PASR will be described later.

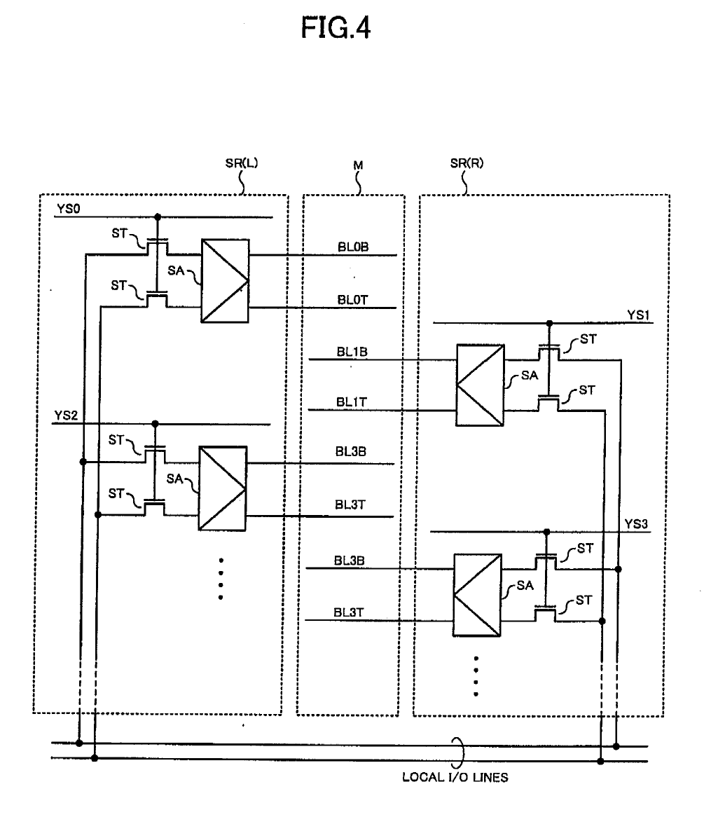

FIG. 4 is a diagram showing a configuration example of the sense amplifier row SR as the above cache memory. Two sense amplifier rows SR(L) and SR(R) are arranged on both sides of the memory mat M. Hereinafter the right side sense amplifier row SR(R) will be described, however the left side sense amplifier row SR(L) has a symmetrical configuration, so the following description is common thereto. In the memory mat M of FIG. 4, two bit lines constitute a bit line pair which serves as a complementary pair, and each bit line pair is alternately connected to the sense amplifier rows SR(L) and SR(R). For example, a bit line pair BL1B and BL1T is connected to the sense amplifier SA in the right side sense amplifier row SR(R).

The sense amplifier SA amplifies a minute potential of each bit line pair BP generated due to accumulate charge of a memory cell. The output side of the sense amplifier SA is connected to a pair of local I/O lines through a pair of select transistors ST. A select control line YS is applied to gates of each pair of select transistors ST, which is different from one another for each bit line pair. In the example of FIG. 4, there are shown a select control line YS1 corresponding to a bit line pair BL1B and BL1T and a select control line YS3 corresponding to a bit line pair BL3B and BL3T, respectively, in the sense amplifier row SR(R). When the select control line YS is activated in response to a column address, the pair of select transistors ST turns on, and the sense amplifier SA can be connected to the local I/O lines.

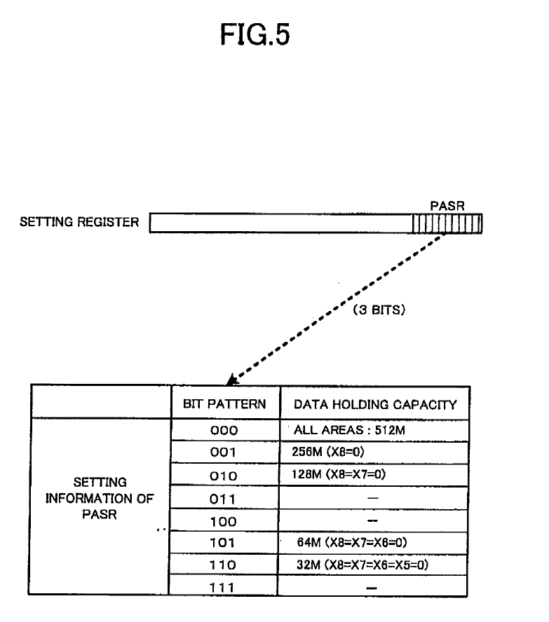

Next, the setting register 17 as the setting means of the invention for storing the setting information of the PASR of the embodiment will be described. FIG. 5 is a diagram showing a specific setting example of the setting register 17. In the setting register 17 as shown in FIG. 5, lower three bits are assigned to the setting information of the PASR, data holding capacity in the PASR can be set in response to the bit pattern of the three bits. Data holding capacity of the holding area to be refreshed in the self refresh operation can be selectively set from five types including “all areas” (512 Mbits), 256 Mbits, 128 Mbits, 64 Mbits and 32 Mbits in the setting register 17. As shown in FIG. 5, a relation between the five types of data holding capacities and patterns of bits X5 to X8 of the row address is shown, but specific operation will be described later.

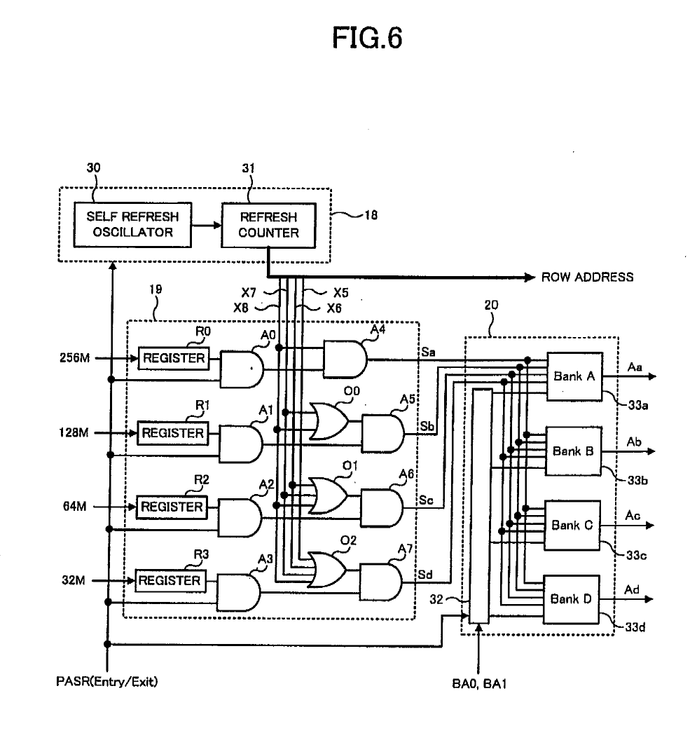

FIG. 6 is a block diagram showing a principal configuration relating to the self refresh operation of the DRAM of the embodiment. In FIG. 6, a portion including the self refresh controller 18, the PASR state controller 19 and the bank activation controller 20 in the entire configuration of FIG. 1 is specifically shown. A PASR Entry/Exit signal is sent to the self refresh controller 18, the PASR state controller 19 and the bank activation controller 20 respectively from the command decoder 16 (FIG. 1) at the start/end of the self refresh operation. Further, control signals corresponding to four types of the data holding capacities (256 Mbits/128 Mbits/64 Mbits/32 Mbits) are sent from the command decoder 16 to the PASR state controller 19 as the setting information of the PASR read from the setting register 17.

The self refresh controller 18 includes a self refresh oscillator 30 and a refresh counter 31. The self refresh oscillator 30 generates an internal clock of a predetermined interval to conforming to the data retention characteristics of the DRAM. The refresh counter 31 is a counter synchronizing with the internal clock of the self refresh oscillator 30, and sequentially outputs a row address to be refreshed corresponding to a count value. As shown in FIG. 6, four bits X5, X6, X7 and X8 of the row address output from the refresh counter 31 are input to the PASR state controller 19.

The PASR state controller 19 includes four registers R0 to R3, eight AND gates A0 to A7, and three OR gates O0 to O2. One of the registers R0 to R3 is set to a high level corresponding to one type of the data holding capacity included in the setting information in the setting register 17, among the above four types of the data holding capacities. The four AND gates A0 to A3 has one input terminals to which outputs of the four registers R0 to R3 are coupled, and the other input terminals to which the above PASR Entry/Exit signal is coupled. Thus, the output of one of the AND gates A0 to A3 changes to a high level, where one input terminal is changed to a high level through one of the registers R0 to R3 in response to the data holding capacity in the setting register 17, and the other input terminal is changed to a high level by the PASR Entry/Exit signal at the start of the self refresh operation.

Meanwhile, the output of the AND gate A0 and the bit X8 of the above row address are input to the AND gate A4. Two bits X7 and X8 of the row address are input to the OR gate O0, and outputs of the AND gate A1 and the OR gate O0 are input to the AND gate A5. Three bits X6 to X8 of the row address are input to the OR gate O1, and outputs of the AND gate A2 and the OR gate O1 are input to the AND gate A6. Four bits X5 to X8 of the row address are input to the OR gate O2, and outputs of the AND gate A3 and the OR gate O2 are input to the AND gate A7. Then, the respective AND gates A4 to A7 output bank stop signals Sa, Sb, Sc and Sd in this order for the banks A, B, C and D.

The bank activation controller 20 includes a bank selection decoder 32 and bank active signal generators 33 (33a, 33b, 33c and 33d) of the banks A to D. The 2-bit bank select address BA0 and BA1 and the PASR Entry/Exit signal are input to the bank selection decoder 32. One decoded signal selected from the four decode signals supplied to the banks A to D, in response to the 2-bit bank select address BA0 and BA1, is only activated in the normal mode. Meanwhile, the four decode signals are activated regardless of the bank select address BA0 and BA1 are activated in response to the PASR Entry/Exit signal during the self refresh period.

The four bank stop signals Sa, Sb, Sc and Sd and a corresponding one of the four decode signals from the bank selection decoder 32 are respectively input to each of the bank active signal generators 33 of the banks A to D, and the bank active signals Aa, Ab, Ac and Ad supplied to the respective banks A to Dare output. For example, the bank active signal generator 33a for the bank A activates the bank active signal Aa for the bank A, when all of the input bank stop signals Sa to Sd are in an inactivated state (low level) and the input decode signal is in an activated state (high level). On the other hand, the bank active signal Aa for the bank A is inactivated when any of the bank stop signals Sa to Sd is in an activated state (high level) or when the input decode signal is in an inactivated state (low level). The same control is performed for the bank active signals Ab, Ac and Ad for the other banks B, C and D.

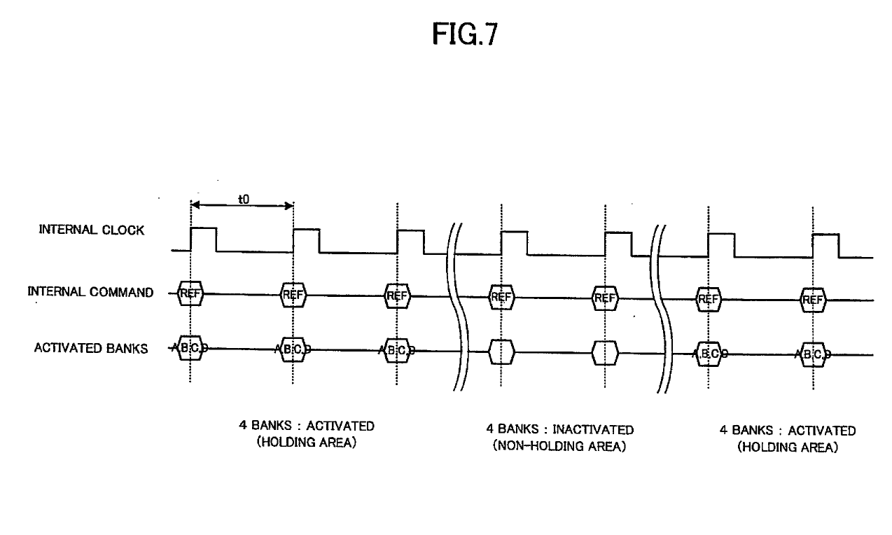

In the configuration of FIG. 6, operation in accordance with the data holding capacity set by the PASR will be described. First, when the PASR is set to “all areas”, all the four bank stop signals Sa, Sb, Sc and Sd output from the PASR state controller 19 are in the inactivated state, and thus all the four bank active signals Aa, Ab, Ac and Ad output from the bank activation controller 20 in the self refresh operation are activated. On the other hand, when the PASR is set for partial areas (256 Mbits, 128 Mbits, 64 Mbits or 32 Mbits), whether the bank stop signals Sa, Sb, Sb and Sd are activated or not is determined depending on the pattern of bits X5 to X8 of the row address. In the following, the self refresh operation in accordance with the data holding capacity of the PASR will be described with reference to FIGS. 7 to 9.

FIG. 7 is a diagram showing a refresh operation during the self refresh period in a case where the holding area corresponding to a predetermined data holding capacity is set for each bank. Hereinafter, lower nine bits of the row address output from the refresh counter 31 are assumed to start from zero for the simplicity. Since the bits X5 to X8 of the row address are zero immediately after the self refresh operation is started, the four banks are simultaneously activated by the bankactive signals Aa to Ad. Thereby, in the respective holding areas of the four banks, four word lines corresponding to a common row address are selected to be refreshed, for which the refresh operation is performed. Meanwhile, when the refresh counter 31 is counted up until the bits X5 to X8 of the row address change, any of the bank stop signals Sa to Sd is activated at a certain timing. Thereby, the four banks become in an inactivated state simultaneously, and the word lines corresponding to respective non-holding areas are not refreshed. In this manner, a time zone in which the holding areas of the four banks are refreshed simultaneously and a time zone in which the non-holding areas of the four banks are not refreshed are repeated.

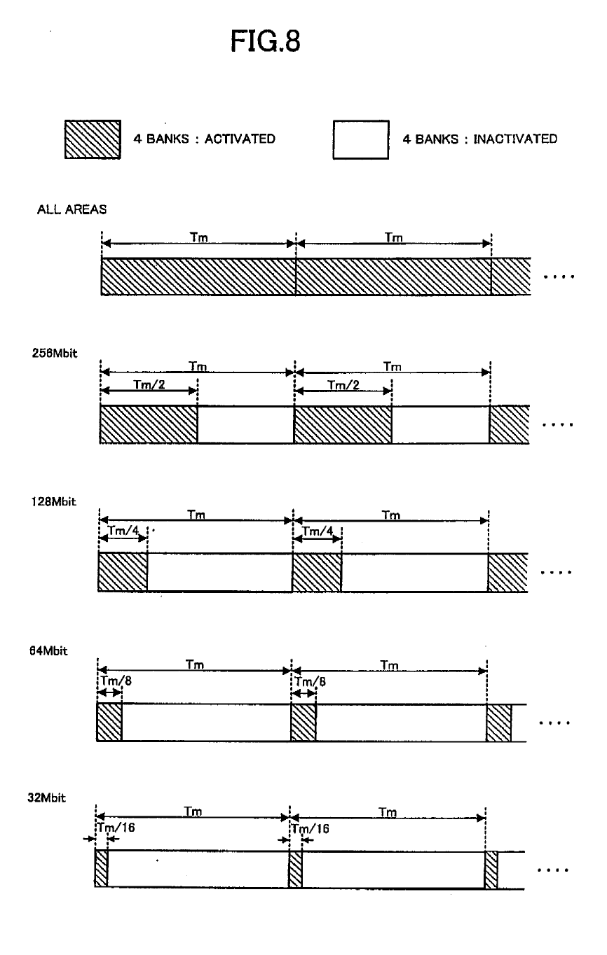

FIG. 8 is a diagram in which the self refresh operations of FIG. 7 for different data holding capacities of the PASR are compared on a time axis. The five types of data holding capacities set in the setting register 17 of FIG. 5 are shown, which includes “all areas”, 256 Mbits, 128 Mbits, 64 Mbits and 32 Mbits in this order. Time zones in which the four banks are simultaneously activated (indicated by hatched squares) and time zones in which the four banks are inactivated (indicated by hollow squares) are shown respectively within a time range of the self refresh operation in which the row address changes in each single memory mat M. A time Tm represents a time required for sequentially refreshing all word lines in a single memory mat M while circulating lower nine bits X0 to X8 of the row address. When 512 word lines are selected in the memory mat M by the nine bits X0 to X8 of the row address, the time Tm satisfies a relation of Tm=512×t0.

First, as shown in FIG. 8, when the data holding capacity is set to “all areas”, the four banks are simultaneously activated in all time zones of the self refresh period and the refresh operation is performed. Meanwhile, when the data holding capacity is set to 256 Mbits, the four banks are simultaneously activated during a time Tm/2 and the refresh operation is performed, and the four banks are inactivated during a remaining time Tm/2. Similarly, as shown in FIG. 8, as the setting of the data holding capacity decreases like 128 Mbits, 64 Mbits, 32 Mbits, the time during which the four banks are simultaneously activated and refreshed decreases in the order of Tm/4, Tm/8 and Tm/16, and the time during which the four banks are in the inactivated state is relatively prolonged.

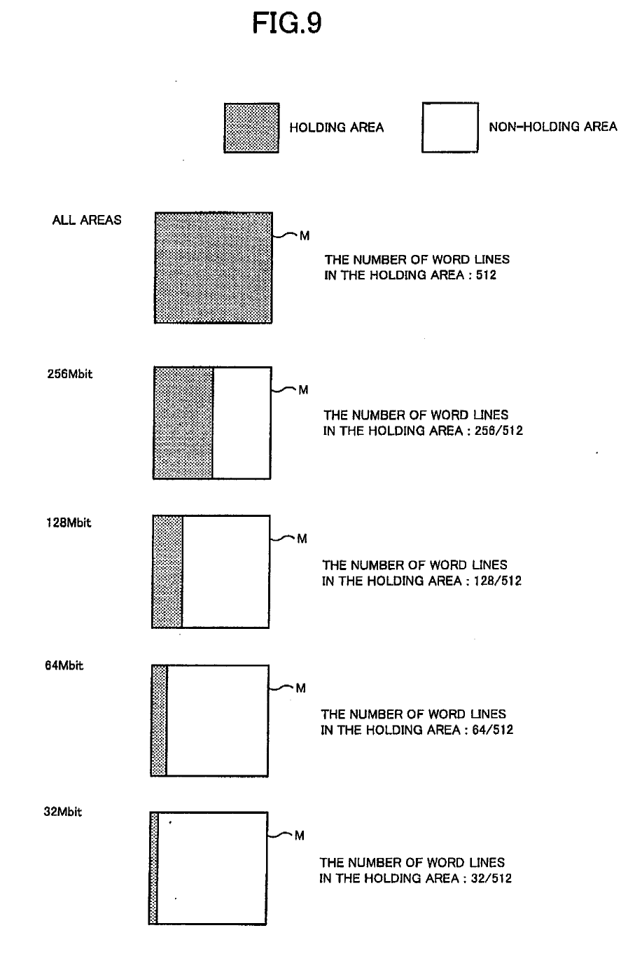

FIG. 9 is a diagram in which different data holding capacities of the PASR are compared, with attention paid to the configuration of the memory mat M. In each of the five types of the data holding capacities as in FIG. 8, there are shown a holding area (indicated by a hatched square) in which data is held in the memory mat M during the self refresh period and a non-holding area (indicated by a hollow square) in which data is not held. In the example of FIG. 9, a case is assumed in which word lines extends in a longitudinal direction in the memory mat M and row addresses thereof increases from left to right. The number of word lines included in the holding area among 512 word lines in the memory mat M is shown for each type of the holding areas. If the data holding capacity is set in the same manner, the configuration of the holding area and the non-holding area is common to all the memory mats M in the four banks.

As shown in FIG. 9, when the data holding capacity is set to “all areas”, the entire memory mat M including 512 word lines is used as the holding area. Meanwhile, when the holding area is set to 256 Mbits, the numbers of word lines in the holding area and the non-holding area are both 256, while being partitioned at a position where the bit X8 changes from zero to one. Similarly, as the data holding capacity is limited to such as 128 Mbits, 64 Mbits and 32 Mbits, the holding area becomes smaller in accordance with the pattern of bits X5 to X8, and the number of word lines in the holding area decreases in the order of 128, 64 and 32. Since a difference between the holding area and the non-holding area can be determined by the row address, data to be held needs to be stored in the holding area, while data allowed to be destroyed during the self refresh period needs to be stored in the non-holding area. Further, data of one page held in the cache memory among data stored in the holding area can be effectively utilized within a time period extending over the self refresh period.

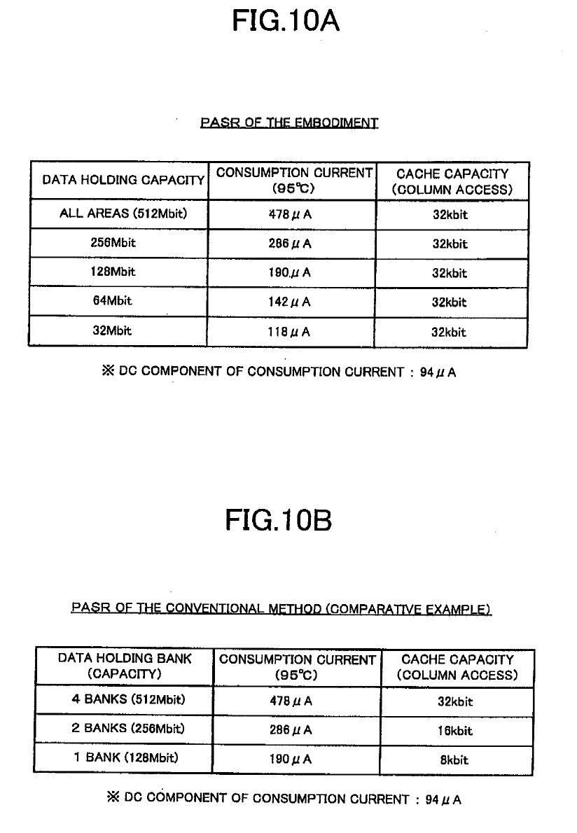

Next, effects in case of employing the PASR of the embodiment will be described using FIGS. 10A and 10B. FIG. 10A shows a table of consumption currents in the standby mode and cache capacities in the column access corresponding to data holding capacities of the PASR, regarding a DRAM having a specification described in the embodiment. Further, FIG. 10B shows a comparative example to FIG. 10A, in which the storage capacity and the bank configuration are the same as in the DRAM of the embodiment, regarding a DRAM employing the conventional PASR for each bank.

As shown in FIG. 10A, the consumption current of the DRAM in the standby mode changes proportionally to the data holding capacity, and it is the same as in FIG. 10B as long as the capacity converted into the number of banks is the same. However the lower limit of data holding capacity of the conventional PASR is one bank, while the data holding capacity of the PASR of the embodiment can be reduced without limitation of the banks so that corresponding consumption current can be reduced. Further, since all the four banks are to be refreshed in the embodiment, the cache capacity in the column access is always maintained to be 32 kbits which is equivalent to the cache capacity of the four banks. On the contrary, as the number of banks for holding data is limited in the conventional PASR, the cache capacity deceases. In this manner, the PASR of the embodiment is advantageous in that the effect of reducing the consumption current due to a reduction in the data holding capacity can be obtained without reducing the cache capacity.

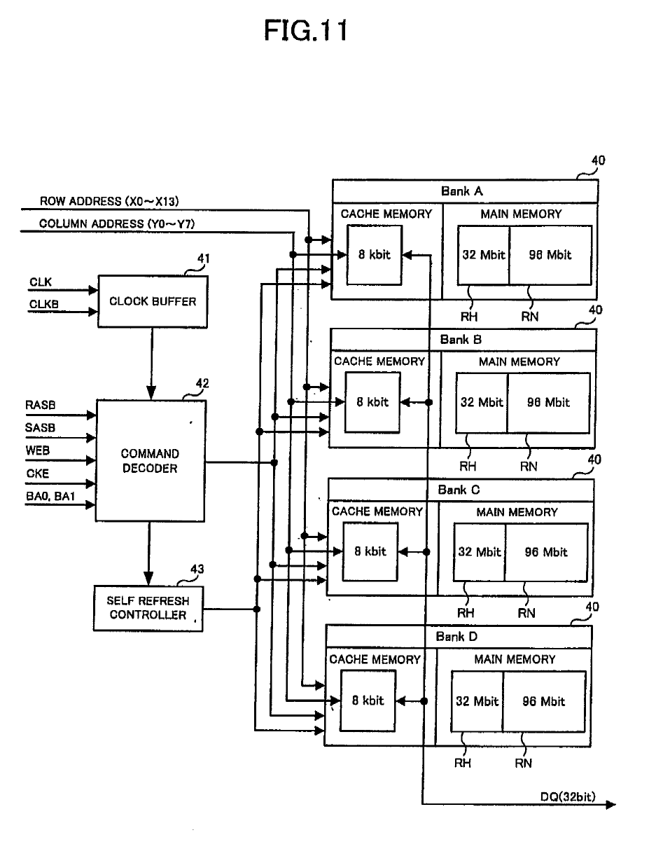

The PASR of the present invention described above are not limited to the application for the DRAM but has various applications. First, a case of applying the concept of the PASR of the present invention to a general memory system will be described using FIG. 11. The memory system as shown in FIG. 11 includes a memory circuit 40 divided into four banks A, B, C and D, a clockbuffer 41, a command decoder 42, and a self refresh controller 43. The memory system configured in this manner is not limited by the specification of the DRAM of the embodiment or the configuration of a semiconductor chip, however a case where the storage capacity and the bank configuration are the same as those in the above described embodiment will be described for the convenience of understanding.

There are provided a 128M-bit main memory and an 8 k-bit cache memory in the memory circuit 40 of each bank, and access to the memory circuit 40 is controlled based on a 14-bit row address (X0 to X13) and an 8-bit column address (Y0 to Y7). Further, the main memory of the memory circuit 40 of each bank is partitioned into a holding area RH and a non-holding area RN, which has the same setting as the data holding capacity of 128M bits. Thus, the storage capacity of the holding area RH is 32 Mbits, which is ¼ of each bank, and the storage capacity of the non-holding area RN is 96 Mbits, which is ¾ of each bank. In FIG. 11, an example of being partitioned into the holding area RH and the non-holding area RN is shown for the simplicity, however many partitioned areas may be included.

The clock buffer 41 generates an internal clock for controlling operation timings based on an input clock CLK and an input inverted clock CLKB. The command decoder 42 determines a command having a pattern of control signals RASB, CASB, WEB and CKE input from outside, and generates a predetermined control signal based on the bank select signal BA0 and BA1. Then, the command decoder 42 supplies the Entry/Exit signal to the self refresh controller 43 at a predetermined timing at the start/end of the self refresh operation. The self refresh controller 43 controls the refresh operation for each bank during the self refresh period, and sequentially supplies a row address corresponding to word lines to be refreshed to the respective banks.

During the self refresh period, only the holding area RH of the main memory of each bank is refreshed, while the non-holding area RN is not refreshed. It is the same as the DRAM of the embodiment in this respect, and the consumption current in the self refresh operation can be reduced. In the normal mode, data of four pages (32 kbits) in total are stored in all cache memories of the four banks, and 32-bit data is transmitted from/to outside through DQ. In this case, each cache memory can be continued to be used within a time period extending over the self refresh period. In this manner, when the PASR of the present invention is applied to the memory system, maximum utilization of the cache capacity and a reduction in current at the self refresh operation can be both achieved.

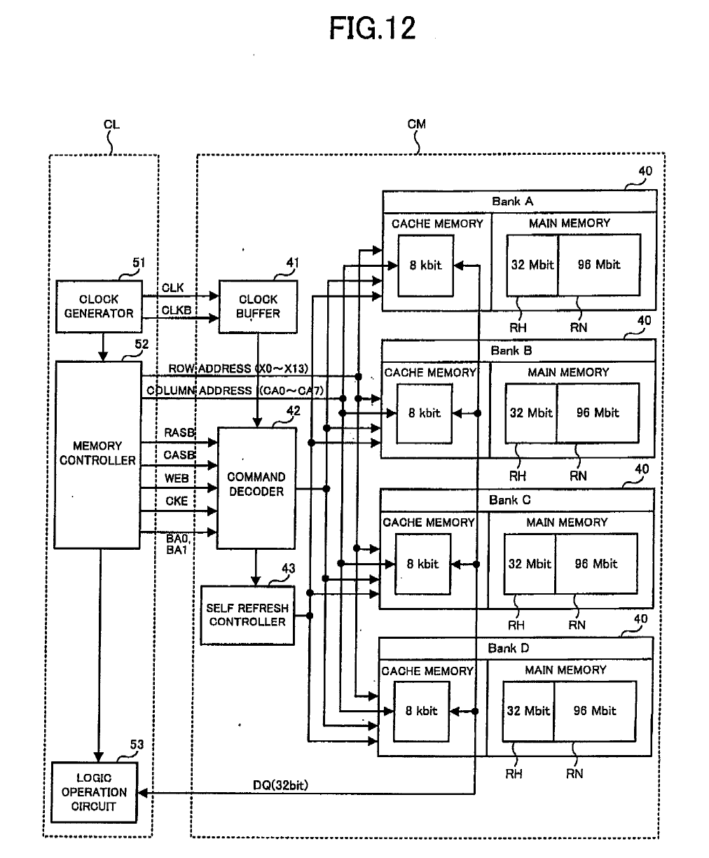

Next, a case of applying the concept of the PASR of the present invention to a SOC (System on chip) as the semiconductor device will be described using FIG. 12. In the SOC as shown in FIG. 12, an entire system including a circuit required for controlling the DRAM is integrated on a chip, in addition to a circuit for achieving the DRAM of the embodiment. The entire SOC as shown in FIG. 12 is divided into a memory integrated circuit CM and a logic integrated circuit CL. Configuration of the memory integrated circuit CM is the same as in FIG. 11, so description thereof will be omitted.

The logic integrated circuit CL includes a clock generator 51, a memory controller 52 and a logic operation circuit 53. The clock generator 51 generates a clock CLK and an inverted clock CLKB each as a timing basis, and supplies them to the clock buffer 41 of the memory integrated circuit CM. The memory controller 52 generates control signals RASB, CASB, WEB, CKE corresponding to the above command, a row address (X0 to X13), a column address (Y0 to Y7), and a bank select signal BA0 and BA1, respectively, and supplies them to the command decoder 42 of the memory integrated circuit CM. The logic operation circuit 53 performs a predetermined operation using the 32-bit data input from each cache memory of the four banks through the DQ under the control of the memory controller 52.

In the SOC of FIG. 12, operation during the self refresh period and its effects are the same as in FIG. 11. In this case, since the effect of reducing the consumption current in the PASR is maintained, while the maximum utilization of the cache capacity can be achieved, thereby the efficiency of operation in the logic operation circuit 53 is improved.

In the forgoing, the present invention has been specifically described based on the embodiment. However, the present invention is not limited to the above embodiment and can be variously modified without deviating from the scope of the invention. For example, the present invention can be applied to a memory cell array 10 divided into an arbitrary number of banks, not only four banks. Similarly, the present invention can be applied to banks having various configurations including, for example, being divided into memory mats M. Further, configuration and operation of the PASR state controller 19 and the bank activation controller 20 are not limited to the embodiment, and various configurations can be employed.

The present invention is not limited to the above described embodiments, and various variations and modifications may be possible without departing from the scope of the present invention.

This application is based on the Japanese Patent application No. 2006-350684 filed on Dec. 26, 2006, entire content of which is expressly incorporated by reference herein.

What is claimed is:

1. A semiconductor memory device comprising:
a memory cell array in which memory cells arranged at intersections between a plurality of word lines and a plurality of bit lines are divided into a plurality of banks;
a plurality of cache memories which is attached to the respective banks and each stores data of a word line selected by a row address;
a setting means for setting a data holding capacity of said memory cell array so that a holding area in which data is held during a self refresh period and a non-holding area in which data is not held during the self refresh period are commonly included in each of the plurality of banks;
a refresh controller for sequentially outputting a row address to be refreshed at predetermined intervals during the self refresh period and for performing a refresh operation for a selected word line corresponding to the row address to be refreshed in an activated bank; and
a bank controller for activating all of the plurality of banks when the selected word line is included in the holding area and inactivating all of the plurality of banks when the selected word line is included in the non-holding area, respectively, based on the row address to be refreshed in a self refresh operation performed at the predetermined intervals.

2. The semiconductor memory device according to claim 1, wherein each of said cache memories is a sense amplifier row including a plurality of sense amplifiers for amplifying data of the memory cells on the selected word line in the bank through the plurality of bit lines.

3. The semiconductor memory device according to claim 1, wherein said setting means is capable of selectively setting one of M types of the data holding capacities each having ½^{N} (N is an integer between 1 and M) of a storage capacity of said memory cell array.

4. The semiconductor memory device according to claim 1, wherein said bank controller determines the holding area and the non-holding area based on a pattern of K bits included in the row address to be refreshed.

5. The semiconductor memory device according to claim 1, wherein each of the banks is divided into a plurality of memory mats each having the same storage capacity, and the holding areas and the non-holding areas are arranged in the respective memory mats.

6. The semiconductor memory device according to claim 5, wherein the row address includes first bits for selecting the memory mat and second bits for selecting the word line in each of the memory mats, and said bank controller determines the holding area and the non-holding area based on a pattern of the second bits.

7. A semiconductor device having a memory integrated circuit and a logic integrated circuit respectively configured on a single chip, wherein
said memory integrated circuit comprises:
a memory cell array in which memory cells arranged at intersections between a plurality of word lines and a plurality of bit lines are divided into a plurality of banks;
a plurality of cache memories which is attached to the respective banks And each stores data of a word line selected by a row address;
a setting means for setting a data holding capacity of said memory cell array so that a holding area in which data is held during a self refresh period and a non-holding area in which data is not held during the self refresh period are commonly included in each of the plurality of banks;
a refresh controller for sequentially outputting a row address to be refreshed at predetermined intervals during the self refresh period and for performing a refresh operation for a selected word line corresponding to the row address to be refreshed in an activated bank; and
a bank controller for activating all of the plurality of banks when the selected word line is included in the holding area and inactivating all of the plurality of banks when the selected word line is included in the non-holding area, respectively, based on the row address to be refreshed in a self refresh operation at the predetermined intervals,
and said logic integrated circuit comprises:
a memory controller for controlling a normal operation of said memory integrate circuit and for controlling start/end of a self refresh operation in said memory cell array; and
an operation means for performing an operation to achieve a predetermined function using at least data stored in said cache memories.

8. The semiconductor device according to claim 7, wherein said memory controller sends a command for setting the data holding capacity for said setting means and a command for indicating the start/end of the self refresh operation, respectively, to said memory integrated circuit.

9. A memory system comprising:
a main memory divided into a plurality of banks;
a plurality of cache memories which is attached to the respective banks and each stores data of an area of each bank selected by an address;
a setting means for setting a data holding capacity of said main memory so that a holding area in which data is held during a self refresh period and a non-holding area in which data is not held during the self refresh period are commonly included in each of the plurality of banks;
a command decoder for controlling a self refresh operation for said main memory when receiving a self refresh request;
a refresh controller for sequentially outputting an address to be refreshed at predetermined intervals during the self refresh period and for performing a refresh operation for a selected area corresponding to the address to be refreshed in an activated bank; and
a bank controller for activating all of the plurality of banks when the selected area is included in the holding area and inactivating all of the plurality of banks when the selected area is included in the non-holding area, respectively, based on the address to be refreshed in the self refresh operation.

10. The memory system according to claim 9 further comprising a memory controller for instructing said main memory to operate in a normal operation and for instructing said main memory to start/end the self refresh operation.

11. A refresh control method for a memory cell array divided into a plurality of banks to each of which a cache memory attached, the method comprising the steps of;
setting a data holding capacity of said memory cell array so that a holding area in which data is held during a self refresh period and a non-holding area in which data is not held during the self refresh period are commonly included in each of the plurality of banks;
instructing a start of the self refresh period;
outputting a row address to be refreshed sequentially at predetermined intervals during the self refresh period;
activating all of the plurality of banks when the selected word line is included in the holding area and inactivating all of the plurality of banks when the selected word line is included in the non-holding area, respectively, based on the row address to be refreshed;
performing a refresh operation for the selected word line corresponding to the row address to be refreshed in activated banks; and
instructing an end of the self refresh period.

12. The refresh control method according to claim 11 wherein the plurality of banks are simultaneously activated and refreshed when selected word lines corresponding to the same row address are included in the holding areas of the plurality of banks.
